(19) United States
(12) Patent Application Publication
(10) Pub. No.: US 2026/0301680 A1
(43) Pub. Date: Oct. 1, 2026

(54) DISPLAY DEVICE AND DISPLAY PANEL

(71) Applicant: LG DISPLAY CO., LTD., Seoul (KR)

(72) Inventors: HwiDeuk LEE, Paju-si (KR); HongSik KIM, Paju-si (KR); YESEUL HAN, Paju-si (KR)

(21) Appl. No.: 19/387,546

(22) Filed: Nov. 12, 2025

(30) Foreign Application Priority Data
Mar. 25, 2025 (KR) 10-2025-0038097

(51) Int. Cl. G09G 3/3266; G06F 3/041; G09G 3/32

(52) U.S. Cl. CPC G09G 3/3266; G06F 3/04182; G09G 3/32; G09G 2300/0413; G09G 2310/0267; G09G 2310/0286; G09G 2380/10

(57) ABSTRACT

A display device and a display panel, the display device including: a base circuit layer including a plurality of gate-in-array units constituting a gate driving circuit in a display area; a pixel layer disposed on the base circuit layer and including a plurality of pixels; a touch electrode layer disposed over the pixel layer and including a plurality of sensing touch electrodes; and a touch driving circuit configured to amplify touch sensing signals transmitted through the plurality of sensing touch electrodes to generate touch sensing data. The plurality of gate-in-array units may include: a first gate circuit block including a first dummy pixel overlapping a first sensing touch electrode; and a second gate circuit block including a second dummy pixel overlapping a second sensing touch electrode.

### CROSS REFERENCE TO RELATED APPLICATION

This application claims priority from and the benefit of Korean Patent Application No. 10-2025-0038097, filed on Mar. 25, 2025, which is hereby incorporated by reference for all purposes as if fully set forth herein.

### BACKGROUND

### Field

Embodiments of the invention relate generally to a display device and a display panel, and more particularly, to a display device and a display panel capable of reducing touch noise and improving touch performance.

### Discussion of the Background

A term “vehicle” refers to a means of transportation that moves people or goods using kinetic energy, and may include various types of transportation means for carrying people, such as automobiles, trucks, buses, aircraft, and ships.

A vehicle may be equipped with a display device including various types of display panels, and a vehicle control device may control information output to the display panel to provide various convenience and safety features to a driver or a passenger.

In the case of a display device used in a vehicle, a gate-in-array (GIA) technique in which a gate driving circuit is disposed in a display area may be applied in order to reduce the size of a non-display area (bezel) of a display panel.

However, when a display panel is configured with a gate-in-array structure, touch noise may be generated at touch electrodes overlapping with the gate driving circuit due to different gate signals, thereby deteriorating touch performance.

The above information disclosed in this Background section is only for understanding of the background of the inventive concepts, and, therefore, it may contain information that does not constitute prior art.

### SUMMARY

Display devices and display panels according to embodiments of the invention are capable of reducing touch noise and improving touch performance in a display panel having a gate-in-array structure.

Display devices and display panels according to embodiments of the invention are also capable of reducing touch noise by arranging dummy pixels in a gate array area overlapping with touch electrodes and applying a common dummy signal thereto.

Additional features of the inventive concepts will be set forth in the description which follows, and in part will be apparent from the description, or may be learned by practice of the inventive concepts.

According to one or more embodiments of the invention, a display device includes: a base circuit layer including a plurality of gate-in-array units constituting a gate driving circuit in a display area; a pixel layer disposed on the base circuit layer and including a plurality of pixels; a touch electrode layer disposed over the pixel layer and including a plurality of sensing touch electrodes; and a touch driving circuit configured to amplify touch sensing signals transmitted through the plurality of sensing touch electrodes to generate touch sensing data. The plurality of gate-in-array units may include a first gate circuit block including a first dummy pixel overlapping a first sensing touch electrode; and a second gate circuit block including a second dummy pixel overlapping a second sensing touch electrode.

The plurality of gate-in-array units may include a first gate circuit area for generating a first scan signal, a second gate circuit area for generating a second scan signal, and a third gate circuit area for generating a light-emission signal. The first gate circuit area, the second gate circuit area, and the third gate circuit area may each include a plurality of gate circuit blocks.

Each of the plurality of gate circuit blocks may include: a sub-circuit area for generating gate signals; a first pixel driving area in which a first driving voltage line for supplying a driving voltage to a first pixel in the pixel layer is disposed; a second pixel driving area in which a second driving voltage line for supplying a driving voltage to a second pixel in the pixel layer is disposed; and a power line area in which selection signal lines for supplying a first selection signal for driving the first pixel and a second selection signal for driving the second pixel are disposed.

The power line area may be disposed between the first pixel driving area and the second pixel driving area.

The first dummy pixel may have a same size as the second dummy pixel.

The first dummy pixel and the second dummy pixel may not overlap with adjacent gate circuit blocks.

A same common signal may be applied to the first dummy pixel and the second dummy pixel.

The touch driving circuit may include a differential amplifier in which the first touch sensing signal from the first sensing touch electrode is supplied to an inverting input terminal, and the second touch sensing signal from the second sensing touch electrode is supplied to a non-inverting input terminal.

The first dummy pixel may be disposed at an end of the first gate circuit block and the second dummy pixel may be disposed at an end of the second gate circuit block.

According to yet another embodiment of the invention, a display panel may include: a base circuit layer including a plurality of gate-in-array units that constitute a gate driving circuit in a display area; a pixel layer disposed on the base circuit layer and including a plurality of pixels; and a touch electrode layer disposed over the pixel layer and including a plurality of sensing touch electrodes. The plurality of gate-in-array units may include a first gate circuit block including a first dummy pixel formed at a location overlapping a first sensing touch electrode; and a second gate circuit block including a second dummy pixel formed at a location overlapping a second sensing touch electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a diagram illustrating the interior of a vehicle according to an embodiment of the invention.

FIG. 2 is a diagram schematically illustrating a structure of a display device according to an embodiment of the invention.

FIG. 3 is an exploded perspective view illustrating a structure of a display panel having a gate-in-array structure according to an embodiment of the invention.

FIG. 4 is an equivalent circuit diagram illustrating a subpixel circuit of a display device according to an embodiment of the invention.

FIG. 5 is a schematic diagram illustrating gate-in-array units formed in a display area of a display panel according to an embodiment of the invention.

FIG. 6 is a plan view illustrating a structure of a gate-in-array unit according to an embodiment of the invention.

FIG. 7 is a plan view comparing a gate circuit block including no dummy pixel with a gate circuit block including a dummy pixel in a first gate circuit area of a display device according to an embodiment of the invention.

FIG. 8 is a plan view comparing a gate circuit block including a dummy pixel in a first gate circuit area with a gate circuit block including a dummy pixel in a second gate circuit area of a display device according to an embodiment of the invention.

FIG. 9 is a diagram illustrating a configuration of a differential amplifier of a touch driving circuit that amplifies touch sensing signals in a display device according to an embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

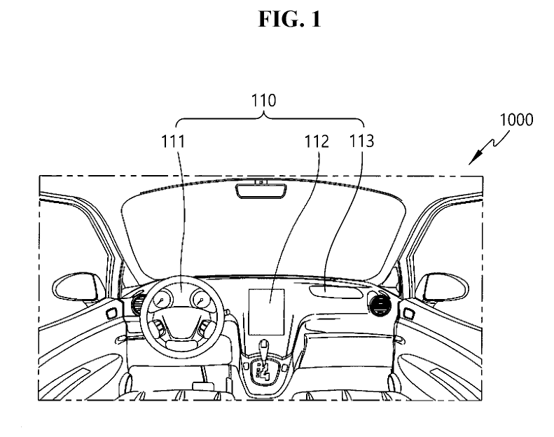

FIG. 1 is a diagram illustrating the interior of a vehicle according to embodiments of the invention.

Referring to FIG. 1, the interior of a vehicle 1000 according to embodiments of the invention may include a driver's seat and a passenger seat, and may include a dashboard located in front of the driver's seat and the passenger seat, where various instruments necessary for driving are arranged, and a center fascia having a control panel for electronic devices.

The dashboard may include a first display panel 111 that displays information necessary for driving, such as a speedometer. The first display panel 111 may be referred to as a dashboard display panel.

The first display panel 111 is a display panel that provides the driver with information on the driving status of the vehicle 1000 and the operation of various electronic devices installed in the vehicle 1000, thereby enabling the vehicle 1000 to be safely driven. It is located behind the steering wheel with respect to the driver's seat, and various information such as a speedometer indicating driving speed, a tripmeter indicating driving distance, a tachometer indicating engine revolutions, a fuel gauge, a coolant temperature gauge, an engine temperature gauge, and various warning lamps may be displayed through the first display panel 111.

The center fascia is located between the driver's seat and the passenger seat and may correspond to an area where the dashboard and the shift lever meet vertically. Components such as an audio controller, an air conditioner, a heater controller, a navigator, air vents, and a cup holder may be disposed in the center fascia. In addition, a second display panel 112 may be included in the center fascia.

The second display panel 112 may display a route to a destination or a map image corresponding to the current location and may provide a user interface related to the control of various electronic devices installed in the vehicle 1000. When the vehicle 1000 is connected to a mobile terminal, a screen provided from the mobile terminal may also be displayed.

The second display panel 112 located between the driver’s seat and the passenger seat of the vehicle 1000 may be referred to as a center fascia display panel.

In addition, a third display panel 113 for the convenience of a passenger seated in the passenger seat may further be provided in front of the passenger seat. The third display panel 113 located at the passenger seat may be referred to as a “passenger seat display panel”.

In addition to the dashboard display panel 111, the center fascia display panel 112, and the passenger seat display panel 113, the display panel 110 may further include at least one of a front window display panel, a side mirror display panel, a rearview mirror display panel, and a side window display panel. Additionally, various other types of display panels may be installed.

The front window display panel may be a display panel that projects a virtual image onto a portion of a front window through which the front of the vehicle 1000 can be viewed. The front window display panel may display vehicle speed, remaining fuel amount, navigation information, etc., thereby minimizing the driver's need to shift their gaze away unnecessarily.

The side mirror display panel may be a display panel that displays an image of a side view captured by a side camera on a portion or entire area of a side mirror configured to allow viewing of the side of the vehicle 1000. Accordingly, the driver may view not only the reflected side image through the side mirror but also the image captured by the side camera via the side mirror display panel.

The rearview mirror display panel may be a display panel that displays an image of the rear view captured by a rear camera on a portion or entire area of a rearview mirror configured to allow viewing of the rear of the vehicle 1000. Accordingly, the driver may view not only the reflected rear image through the rearview mirror but also the image captured by the rear camera via the rearview mirror display panel.

The side window display panel may be a display panel that projects a virtual image onto a portion of a side window through which the side of the vehicle 1000 can be viewed. Various types of vehicle-related information may be displayed through the side window display panel.

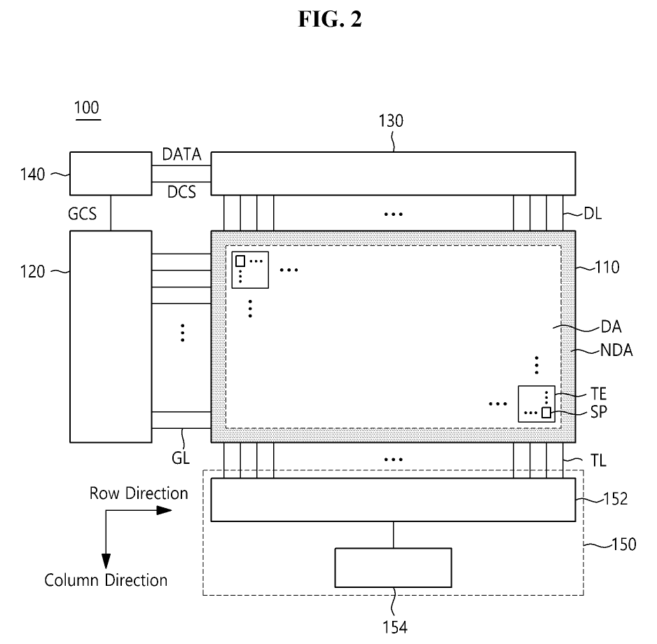

FIG. 2 is a diagram schematically illustrating the structure of a display device according to embodiments of the invention.

Referring to FIG. 2, a display device 100 according to embodiments of the invention may include components for image display, such as a display panel 110, a data driving circuit 130, a gate driving circuit 120, and a timing controller 140.

The display panel 110 may include the dashboard display panel 111, the center fascia display panel 112, and the passenger seat display panel 113.

The display panel 110 may include a display area DA where images are displayed and a non-display area NDA where images are not displayed.

The non-display area NDA may be an outer region of the display area DA and may also be referred to as a “bezel area”. The non-display area NDA may be an area visible from the front of the display device 100 or may be a bent area not visible from the front of the display device 100.

The display panel 110 may include a plurality of subpixels SP. For example, the display device 100 may be any type of display device including a liquid crystal display device, an organic light-emitting display device, a micro light-emitting diode (Micro LED) display device, a quantum dot display device, etc. However, embodiments of the invention are not limited thereto.

The structure of each of a plurality of subpixels SP may vary depending on the type of the display device 100. For example, when the display device 100 is a self-emissive display device in which each subpixel SP emits light on its own, each subpixel SP may include a light emitting element that emits light, one or more transistors, and one or more capacitors.

The display panel 110 may further include various types of signal lines for driving the plurality of subpixels SP. For example, the signal lines may include a plurality of data lines DL that deliver data signals (also referred to as data voltages or image data), and a plurality of gate lines GL that deliver gate signals (also referred to as scan signals or light-emission signals).

The plurality of data lines DL and the plurality of gate lines GL may intersect with each other. Each of the plurality of data lines DL may extend in a column direction. Each of the plurality of gate lines GL may extend in a row direction.

The data driving circuit 130 may be a circuit configured to drive the plurality of data lines DL. The data driving circuit 130 may output data signals to the plurality of data lines DL. The gate driving circuit 120 may be a circuit configured to drive the plurality of gate lines GL, and may output gate signals to the plurality of gate lines GL.

The timing controller 140 may control the data driving circuit 130 and the gate driving circuit 120. The timing controller 140 may control the driving timing of the plurality of data lines DL and the plurality of gate lines GL.

The timing controller 140 may supply various types of data driving control signals DCS to the data driving circuit 130 to control the data driving circuit 130, and may supply various types of gate driving control signals GCS to the gate driving circuit 120 to control the gate driving circuit 120.

The data driving circuit 130 may supply data signals to the plurality of data lines DL in accordance with the driving timing control of the timing controller 140. The data driving circuit 130 may receive image data DATA in digital form from the timing controller 140, convert the received image data DATA into analog data signals, and output the analog data signals to the plurality of data lines DL. The data driving circuit 130 may include one or more source driving integrated circuits (SDICs).

The gate driving circuit 120 may supply gate signals to the plurality of gate lines GL in accordance with timing control of the timing controller 140. The gate driving circuit 120 may receive a first gate voltage corresponding to a turn-on level and a second gate voltage corresponding to a turn-off level, along with various gate driving control signals GCS, to generate gate signals and supply the generated gate signals to the plurality of gate lines GL.

The gate driving circuit 120 may be disposed outside the display panel 110, or may be disposed within the non-display area NDA or the display area DA of the display panel 110. The gate driving circuit 120 may include one or more gate driving integrated circuits (GDICs).

The display device 100 may further include a touch screen panel and a touch circuit 150 for sensing the touch screen panel to detect whether a touch is made by a touch object such as a finger or a pen, or to detect a touch position, in order to provide a touch sensing function in addition to image display.

The touch circuit 150 may include a touch driving circuit 152 configured to drive and sense the touch screen panel and to generate and output touch sensing data, and a touch controller 154 configured to detect the occurrence of a touch or to detect a touch position based on the touch sensing data.

The touch screen panel may include a plurality of touch electrodes TE as touch sensors. The touch screen panel may further include a plurality of touch lines TL configured to electrically connect the plurality of touch electrodes TE and the touch driving circuit 152. The touch screen panel or the touch electrodes TE may serve as a touch sensor.

The touch screen panel may be located outside the display panel 110 or inside the display panel 110. When the touch screen panel is located outside the display panel 110, it may be referred to as an “external” touch screen panel. In the case of an external touch screen panel, the touch screen panel and the display panel 110 may be manufactured separately and then combined. The external touch screen panel may include a substrate and a plurality of touch electrodes TE on the substrate.

When the touch screen panel is located inside the display panel 110, it may be referred to as an “internal” touch screen panel. In the case of an internal touch screen panel, the touch screen panel may be formed within the display panel 110 during the manufacturing process of the display panel 110.

The touch driving circuit 152 may supply a touch driving signal to at least one of the plurality of touch electrodes TE and may detect a touch sensing signal transmitted from at least one of the plurality of touch electrodes TE to generate touch sensing data.

The touch circuit 150 may perform touch sensing based on a self-capacitance sensing method or a mutual-capacitance sensing method. However, embodiments of the invention are not limited thereto.

According to the mutual-capacitance sensing method, the plurality of touch electrodes TE may include driving touch electrodes and sensing touch electrodes. The touch driving circuit 152 may drive the driving touch electrodes using touch driving signals and may detect touch sensing signals from the sensing touch electrodes.

According to the self-capacitance sensing method, each of the plurality of touch electrodes TE may serve as both a driving touch electrode and a sensing touch electrode. The touch driving circuit 152 may drive all or part of the plurality of touch electrodes TE and may sense all or part of the plurality of touch electrodes TE.

The touch driving circuit 152 and the touch controller 154 may be implemented as separate devices or as a single device.

The display device 100 according to embodiments of the invention may be a self-emissive display device in which a light emitting element capable of self-emission is disposed on the display panel 110, such as an organic light-emitting display device, a quantum dot display device, or a micro LED display device.

In this case, the gate driving circuit 120 may be implemented in a gate-in-panel (GIP) form directly formed in the non-display area NDA of the display panel 110, or in a gate-in-array form formed in the display area DA of the display panel 110.

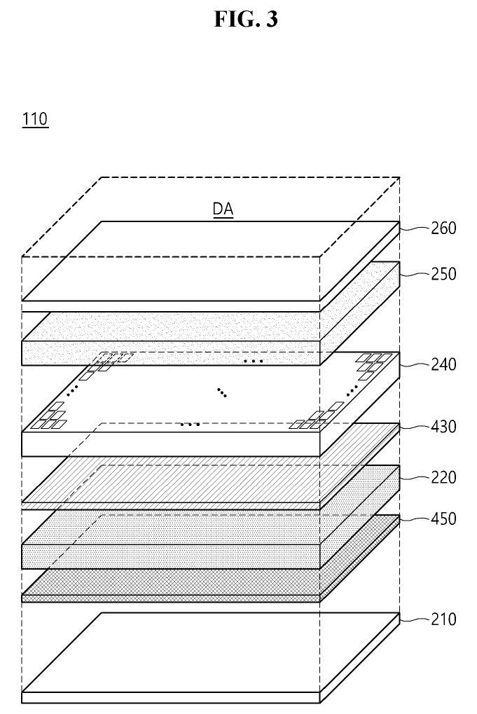

FIG. 3 is an exploded perspective view illustrating a structure of a display panel having a gate-in-array structure according to embodiments of the invention.

Referring to FIG. 3, the display panel 110 according to embodiments of the invention may include a substrate 210, a base circuit layer 220, a pixel layer 240, an encapsulation layer 250, and a touch electrode layer 260.

The pixel layer 240 may be a layer in which a plurality of subpixels SP are formed, and may be located on the substrate 210. The pixel layer 240 may include a plurality of subpixels SP arranged in the display area DA where images are displayed.

The base circuit layer 220 may be a layer in which the gate driving circuit 120 is formed in a gate-in-array type. The base circuit layer 220 may be located between the substrate 210 and the pixel layer 240. The base circuit layer 220 may include the gate driving circuit 120 in a gate-in-array type.

For example, the base circuit layer 220 may include a plurality of gate driving integrated circuits (GDICs) disposed across the entire display area DA. In another example, the base circuit layer 220 may include a plurality of gate driving integrated circuits (GDICs) disposed in at least a portion of the display area DA.

The base circuit layer 220 may include a gate voltage line for delivering a gate high voltage (VGH) or a gate low voltage (VGL) supplied to the gate driving integrated circuits (GDICs). In addition, the base circuit layer 220 may include a control signal line for supplying control signals for controlling the gate driving integrated circuits (GDICs).

In another example, the base circuit layer 220 may further include two or more driving voltage lines to which two or more subpixel voltages supplied to the pixel layer 240 are applied.

For example, the two or more subpixel voltages may include a high-potential subpixel voltage EVDD and a low-potential subpixel voltage EVSS supplied to the pixel layer 240. However, embodiments of the invention are not limited thereto. The two or more driving voltage lines may be electrically connected to patterns (e.g., metals) in the pixel layer 240.

The encapsulation layer 250 may be located on the pixel layer 240. The encapsulation layer 250 may prevent an organic film disposed in the pixel layer 240 from being exposed to moisture or oxygen.

On an upper surface of the encapsulation layer 250, the touch electrode layer in which touch electrodes are formed may be disposed.

In the case of a mutual-capacitance sensing method, the touch electrode layer 260 may include driving touch electrodes to which touch driving signals are supplied, and sensing touch electrodes that detect touch sensing signals.

In the display device 100 according to embodiments of the invention, the gate driving circuit 120 is disposed in the display area DA, which can significantly reduce the size of the non-display area NDA.

In addition, in the display device 100 according to embodiments of the invention, because the pixel voltage lines and gate voltage lines are disposed in the display area DA, the size of the non-display area NDA can be further reduced.

The display panel 110 according to embodiments of the invention may include a first shielding layer 430 located between the base circuit layer 220 and the pixel layer 240.

The first shielding layer 430 may shield an electric field between the base circuit layer 220 and the pixel layer 240. Accordingly, the base circuit layer 220 and the pixel layer 240 can reduce unintended electrical influence between them.

The display panel 110 according to embodiments of the invention may include a second shielding layer 450 located between the base circuit layer 220 and the substrate 210.

The second shielding layer 450 may not only shield an electric field between the base circuit layer 220 and the substrate 210, but may also reduce electrical interference between signal wirings of the gate driving integrated circuits (GDICs) formed in the base circuit layer 220.

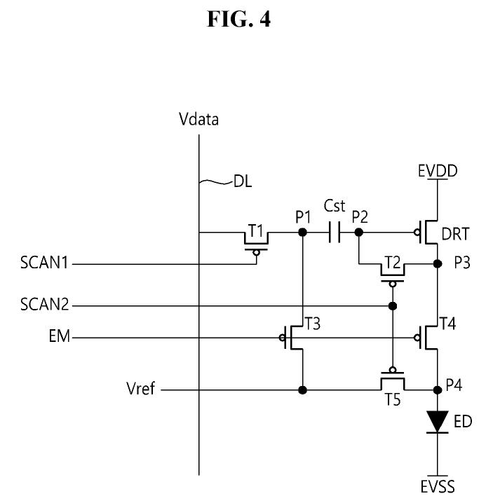

FIG. 4 is an equivalent circuit diagram illustrating a subpixel circuit in a display device according to embodiments of the invention.

Referring to FIG. 4, the subpixel circuit of the display device 100 according to embodiments of the invention may include a light emitting element ED, a driving transistor DRT, a plurality of switching transistors T1 to T5, and a storage capacitor Cst.

The driving transistor DRT and the plurality of switching transistors T1 to T5 included in the subpixel circuit may be implemented as PMOS-type LTPS (Low Temperature Poly Silicon) transistors, and thereby desired response characteristics may be secured.

Alternatively, at least one of the plurality of the switching transistors T1 to T5 may be implemented as an NMOS-type or PMOS-type oxide transistor having good leakage current characteristics in the off state, and the remaining switching transistors may be implemented as PMOS-type LTPS transistors having good response characteristics.

The light emitting element ED emits light by a driving current controlled according to a gate-to-source voltage Vgs of the driving transistor DRT. An anode electrode of the light emitting element ED is connected to a fourth node P4, and a cathode electrode of the light emitting element ED is connected to a low-potential subpixel voltage EVSS.

When the light emitting element ED is an organic light-emitting diode, an organic compound layer is provided between the anode and cathode electrodes.

The organic compound layer may include a hole injection layer (HIL), a hole transport layer (HTL), an emission layer (EML), an electron transport layer (ETL), and an electron injection layer (EIL). For example, two or more organic compound layers that emit different colors may be stacked in a tandem structure.

When a driving current flows through the light emitting element ED, holes passing through the hole transport layer (HTL) and electrons passing through the electron transport layer (ETL) move to the emission layer (EML) to form excitons, and as a result, the emission layer (EML) may emit visible light.

The driving transistor DRT controls a current flowing into the light emitting element ED according to the gate-to-source voltage Vgs. A gate electrode of the driving transistor DRT is connected to a second node P2, a drain electrode (or source electrode) is connected to a line supplying a high-potential subpixel voltage EVDD, and a source electrode (or drain electrode) is connected to a third node P3.

The subpixel circuit may include the first to fifth switching transistors T1 to T5 and the storage capacitor Cst, which are configured to sample the gate-to-source voltage Vgs to compensate for the threshold voltage or mobility of the driving transistor DRT.

The first switching transistor T1 is connected between a data line DL and a first node P1 and is switched by a first scan signal SCAN1. A gate electrode of the first switching transistor T1 is connected to a first gate line to which the first scan signal SCAN1 is applied, a drain electrode (or source electrode) is connected to the data line DL, and a source electrode (or drain electrode) is connected to the first node P1.

The second switching transistor T2 is connected between a second node P2 and a third node P3 and is switched by a second scan signal SCAN2. A gate electrode of the second switching transistor T2 is connected to a second gate line to which the second scan signal SCAN2 is applied, a drain electrode (or source electrode) is connected to the third node P3, and a source electrode (or drain electrode) is connected to the second node P2.

Because one electrode of the second switching transistor T2 is connected to the gate electrode of the driving transistor DRT, it is desirable to have good off-current characteristics. Accordingly, the second switching transistor T2 may be designed with a dual-gate structure to suppress leakage current in the off state.

In a dual-gate structure, the first gate electrode and the second gate electrode are connected to have the same potential, and the channel length becomes greater than that of a single-gate structure. When the channel length increases, the resistance increases and the leakage current in the off state decreases, thereby improving operational stability. However, the second switching transistor T2 may also be implemented with a single-gate structure, in which case it may be implemented as an oxide transistor.

The third switching transistor T3 is connected between the first node P1 and a reference voltage line to which a reference voltage Vref is applied, and is switched by a light-emission signal EM. A gate electrode of the third switching transistor T3 is connected to a third gate line to which the light-emission signal EM is applied, a drain electrode (or source electrode) is connected to the first node P1, and a source electrode (or drain electrode) is connected to the reference voltage line.

The fourth switching transistor T4 is connected between the third node P3 and the fourth node P4, which is an anode electrode of the light emitting element ED, and is switched by the light-emission signal EM. A gate electrode of the fourth switching transistor T4 is connected to the third gate line to which the light-emission signal EM is applied, a drain electrode (or source electrode) is connected to the third node P3, and a source electrode (or drain electrode) is connected to the fourth node P4. Because the fourth switching transistor T4 controls a driving current flowing into the light emitting element ED, it may be referred to as a “light-emission control” transistor.

The fifth switching transistor T5 is connected between the fourth node P4 and the reference voltage line and is switched by the second scan signal SCAN2. A gate electrode of the fifth switching transistor T5 is connected to the second gate line to which the second scan signal SCAN2 is applied, a drain electrode (or source electrode) is connected to the fourth node P4, and a source electrode (or drain electrode) is connected to the reference voltage line.

The storage capacitor Cst is connected between the first node P1 and the second node P2.

As described above, when the subpixel circuit is composed of six transistors (DRT, T1 to T5) and one capacitor (1C), it may be referred to as a 6T1C structure. In this case, gate signals for driving the subpixel circuit may include the first scan signal SCAN1, the second scan signal SCAN2, and the light-emission signal EM.

As described above, when the gate signals include the first scan signal SCAN1, the second scan signal SCAN2, and the light-emission signal EM, and the gate driving circuit 120 is formed in a gate-in-array structure, the base circuit layer 220 in the display area DA may include a plurality of gate-in-array units for generating the gate signals.

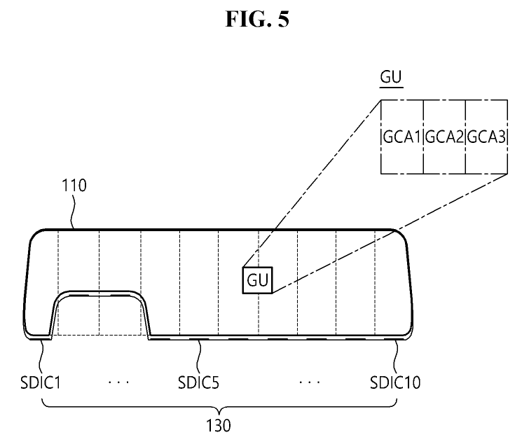

FIG. 5 is a schematic diagram illustrating gate-in-array units formed in the display area of the display panel in a display device according to embodiments of the invention.

Referring to FIG. 5, in the display device 100 according to embodiments of the invention, when the gate driving circuit 120 is formed in a gate-in-array structure, a gate-in-array unit GU that constitutes the gate driving circuit 120 may be located in the display area DA.

For example, when the subpixel circuit has a 6T1C structure and the first scan signal SCAN1, the second scan signal SCAN2, and the light-emission signal EM are used as gate signals, the gate-in-array unit GU may include a first gate circuit area GCA1 for generating the first scan signal SCAN1, a second gate circuit area GCA2 for generating the second scan signal SCAN2, and a third gate circuit area GCA3 for generating the light-emission signal EM.

The structure of the gate-in-array unit GU may be modified according to the structure of gate signals when the subpixel circuit is different.

The first gate circuit area GCA1, the second gate circuit area GCA2, and the third gate circuit area GCA3, which constitute the gate-in-array unit GU, may be sequentially and repeatedly arranged, but the arrangement may be variously changed depending on the structure of the display panel 110.

The shape of the display panel 110 used in the vehicle 1000 may vary depending on its position, and the source driving integrated circuits SDIC1 to SDIC10, which constitute the data driving circuit 130, may be arranged according to the shape of the display panel 110. As an example, the data driving circuit 130 is composed of ten source driving integrated circuits SDIC1 to SDIC10, which are arranged along the lower edge of the display panel 110.

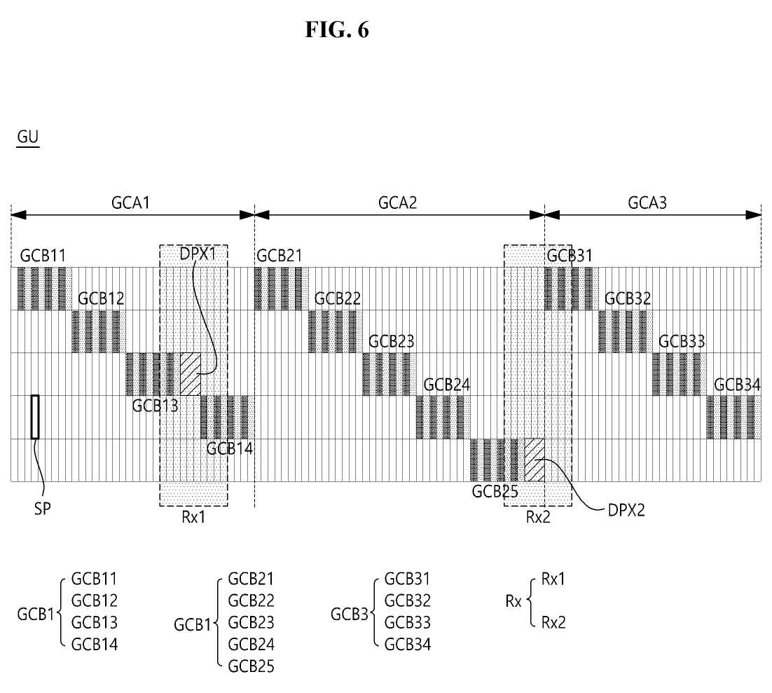

FIG. 6 is a plan view illustrating a structure of a gate-in-array unit in a display device according to embodiments of the invention.

Referring to FIG. 6, in the display device 100 according to embodiments of the invention, the gate-in-array unit GU located in the display area DA of the display panel 110 may include a first gate circuit area GCA1 for generating the first scan signal SCAN1, a second gate circuit area GCA2 for generating the second scan signal SCAN2, and a third gate circuit area GCA3 for generating the light-emission signal EM.

The first gate circuit area GCA1, the second gate circuit area GCA2, and the third gate circuit area GCA3 may be formed in the base circuit layer 220, and a pixel layer 240 in which a plurality of subpixels SP are formed may be formed on an upper surface of the base circuit layer 220. The subpixels SP may include red subpixels, green subpixels, or blue subpixels, and may further include white subpixels.

The first gate circuit area GCA1 may include a plurality of first gate circuit blocks GCB1 configured to generate the first scan signal SCAN1 for driving subpixel circuits located on the same line.

The plurality of first gate circuit blocks GCB1 may be arranged in the first gate circuit area GCA1 so as not to overlap with each other. As an example, four first gate circuit blocks GCB11, GCB12, GCB13, and GCB14 are formed in the first gate circuit area GCA1.

In this case, a touch electrode layer 260 may be disposed on an upper surface of the pixel layer 240. In a mutual-capacitance structure, the touch electrode layer 260 may include a driving touch electrode (not shown) for delivering a touch driving signal and a sensing touch electrode Rx for delivering a touch sensing signal.

Because the display panel 110 having a gate-in-array structure forms the driving touch electrodes and the sensing touch electrodes Rx based on the total number of pixels, the gate circuit blocks located below each sensing touch electrode Rx may differ from one another.

In this case, gate noise generated by gate clock signals for driving the gate driving circuit 120 may be coupled into the touch sensing signal transmitted through the sensing touch electrode Rx. As a result, the touch driving circuit 152 may amplify the touch sensing signal including gate noise, which may lead to degradation in touch performance.

The display device 100 of the invention may reduce touch noise and improve touch performance by arranging a dummy pixel in a gate circuit block located at a position overlapping the sensing touch electrode Rx and by applying a common dummy signal through the dummy pixel.

For example, four first gate circuit blocks GCB11, GCB12, GCB13, and GCB14, including the first-to-first to first-to-fourth gate circuit blocks GCB11 to GCB14, may be located in the first gate circuit area GCA1. In this case, a first sensing touch electrode Rx1 formed on an upper surface may overlap with a portion of the first-to-third gate circuit block GCB13 and a portion of the first-to-fourth gate circuit block GCB14.

In this case, a first dummy pixel DPX1 may be additionally formed in the first-to-third gate circuit block GCB13 located in the first gate circuit area GCA1. The first dummy pixel DPX1 may be formed to extend from an end of the first-to-third gate circuit block GCB13. In this case, the first-to-third gate circuit block GCB13 may be regarded as having a structure that includes the first dummy pixel DPX1.

When the first dummy pixel DPX1 is included in the first-to-third gate circuit block GCB13, the first-to-fourth gate circuit block GCB14 may be formed at a position that does not overlap with the first-to-third gate circuit block GCB13.

When the first dummy pixel DPX1 is formed in the first-to-third gate circuit block GCB13 and a common signal for noise cancellation is applied to the first dummy pixel DPX1, the influence of touch noise on the first touch sensing signal transmitted through the first sensing touch electrode Rx1 may be reduced.

In addition, five second gate circuit blocks GCB21 to GCB25, including the second-to-first to second-to-fifth gate circuit blocks GCB21 to GCB25, may be located in the second gate circuit area GCA2. The number of gate circuit blocks in each gate circuit area may vary depending on the pixel structure of the display panel 110.

In this case, a second sensing touch electrode Rx2 formed in the touch electrode layer 260 may overlap with a portion of the second-to-fifth gate circuit block GCB25.

In this case, a second dummy pixel DPX2 may be additionally formed in the second-to-fifth gate circuit block GCB25 located in the second gate circuit area GCA2. The second dummy pixel DPX2 may be formed to extend from an end of the second-to-fifth gate circuit block GCB25. In this case, the second-to-fifth gate circuit block GCB25 may be regarded as having a structure that includes the second dummy pixel DPX2.

When the second dummy pixel DPX2 is included in the second-to-fifth gate circuit block GCB25, the third gate circuit area GCA3 may be formed at a position that does not overlap with the second-to-fifth gate circuit block GCB25.

When the common signal for noise cancellation is applied to the second dummy pixel DPX2 in a state where the second dummy pixel DPX2 is formed in the second-to-fifth gate circuit block GCB25, the influence of touch noise on a second touch sensing signal transmitted through the second sensing touch electrode Rx2 may be reduced.

In this case, the size of the first dummy pixel DPX1 formed in the first gate circuit area GCA1 may be formed to be the same as the size of the second dummy pixel DPX2 formed in the second gate circuit area GCA2.

In this state, the same common signal may be applied to the first dummy pixel DPX1 and the second dummy pixel DPX2. Accordingly, the touch driving circuit 152, which receives touch sensing signals through the first sensing touch electrode Rx1 and the second sensing touch electrode Rx2, may cancel noise caused by gate signals using the same common signal applied to the first dummy pixel DPX1 and the second dummy pixel DPX2.

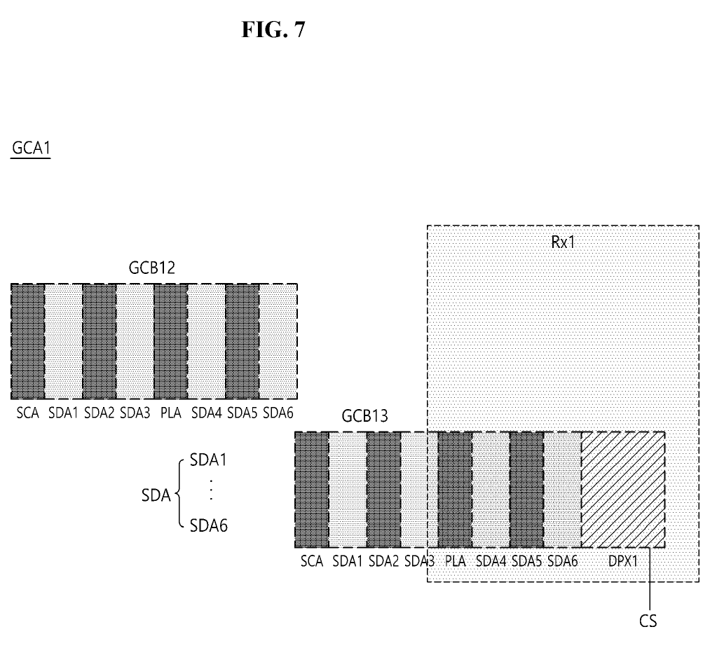

FIG. 7 is a plan view comparing a gate circuit block that does not include a dummy pixel with a gate circuit block that includes a dummy pixel in the first gate circuit area in a display device according to embodiments of the invention.

Referring to FIG. 7, in the display device 100 according to embodiments of the invention, the first gate circuit area GCA1 may include a plurality of gate circuit blocks GCB11 to GCB14 in which the gate driving circuit 120 is formed.

In this case, among the plurality of gate circuit blocks GCB11 to GCB14, the first-to-third gate circuit block GCB13 located at a position overlapping with the first sensing touch electrode Rx1 may include the first dummy pixel DPX1 to which the common signal CS may be applied. On the other hand, the remaining gate circuit blocks GCB11, GCB12, and GCB14 may not include a dummy pixel.

The first-to-second gate circuit block GCB12 may include a sub-circuit area SCA, a plurality of subpixel driving areas SDA, and a power line area PLA. For example, the first-to-second gate circuit block GCB12 may include one sub-circuit area SCA, six subpixel driving areas SDA1 to SDA6, and one power line area PLA, at positions corresponding to eight subpixels SP.

A gate driving circuit having a gate-in-array structure may be located in the sub-circuit area SCA.

In the six subpixel driving areas SDA1 to SDA6, a high-potential subpixel voltage line, a data line, and a reference voltage line for driving the first to sixth subpixels, respectively, may be disposed. These lines, including the high-potential subpixel voltage line, the data line, and the reference voltage line, may be referred to as driving voltage lines.

That is, the first subpixel driving area SDA1 may include a first high-potential subpixel voltage line, a first data line, and a first reference voltage line for driving the first subpixel. Similarly, the second subpixel driving area SDA2 may include a second high-potential subpixel voltage line, a second data line, and a second reference voltage line for driving the second subpixel. The third subpixel driving area SDA3 may include a third high-potential subpixel voltage line, a third data line, and a third reference voltage line for driving the third subpixel.

In addition, the fourth subpixel driving area SDA4 may include a fourth high-potential subpixel voltage line, a fourth data line, and a fourth reference voltage line for driving the fourth subpixel. The fifth subpixel driving area SDA5 may include a fifth high-potential subpixel voltage line, a fifth data line, and a fifth reference voltage line for driving the fifth subpixel. The sixth subpixel driving area SDA6 may include a sixth high-potential subpixel voltage line, a sixth data line, and a sixth reference voltage line for driving the sixth subpixel.

In the display device 100 of the invention, a first pixel and a second pixel having different emission angles may be arranged together, and by selectively controlling the driving of the first pixel or the second pixel, the viewing angle of an image may be controlled.

The first pixel and the second pixel may be collectively referred to as a “unit pixel”. In this case, the first to third subpixels may form the first pixel, and the fourth to sixth subpixels may form the second pixel. Accordingly, the first to third subpixel driving areas SDA1 to SDA3 may be referred to as first pixel driving areas, and the fourth to sixth subpixel driving areas SDA4 to SDA6 may be referred to as second pixel driving areas.

In this case, the gate driving circuit 120 of the display device 100 of the invention may generate a first selection signal for driving the first pixel and a second selection signal for driving the second pixel, and the first and second selection signal lines may be disposed in the power line area PLA. In addition, the power line area PLA may additionally include a high-potential subpixel voltage line.

The gate signal output from the sub-circuit area SCA may be supplied from the base circuit layer 220 to the subpixels SP arranged in the pixel layer 240.

In addition, the first-to-third gate circuit block GCB13 located at a position overlapping the first sensing touch electrode Rx1 in the first gate circuit area GCA1 may include the sub-circuit area SCA, the plurality of subpixel driving areas SDA1 to SDA6, and the power line area PLA. In this case, the first-to-third gate circuit block GCB13 may further include the first dummy pixel DPX1 to which the common signal CS may be applied.

The first dummy pixel DPX1 may be formed in a range that does not overlap with adjacent gate circuit blocks (e.g., GCB12 and GCB14). The first dummy pixel DPX1 may receive the common signal CS, thereby reducing noise affecting the first sensing touch electrode Rx1.

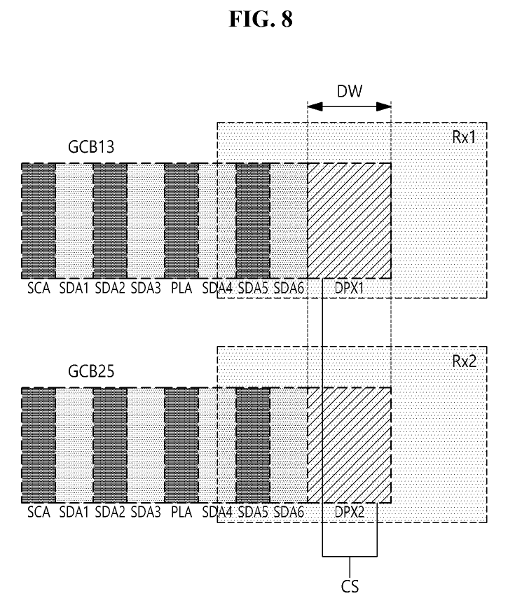

FIG. 8 is a plan view comparing a gate circuit block including a dummy pixel in the first gate circuit area and a gate circuit block including a dummy pixel in the second gate circuit area in a display device according to embodiments of the invention.

Referring to FIG. 8, in the display device 100 according to embodiments of the invention, the first gate circuit area GCA1 in the display area DA of the display panel 110 may include the first-to-first to first-to-fourth gate circuit blocks GCB11 to GCB14. In addition, the second gate circuit area GCA2 may include the second-to-first to second-to-fifth gate circuit blocks GCB21 to GCB25.

In this case, the first-to-third gate circuit block GCB13 located at a position overlapping the first sensing touch electrode Rx1 in the first gate circuit area GCA1 may include the first dummy pixel DPX1. Additionally, the second-to-fifth gate circuit block GCB25 located at a position overlapping the second sensing touch electrode Rx2 in the second gate circuit area GCA2 may include the second dummy pixel DPX2.

The first dummy pixel DPX1 and the second dummy pixel DPX2 may be formed to have the same size, and for this purpose, they may be formed to have the same width DW. Additionally, the same common signal CS may be applied to the first dummy pixel DPX1 and the second dummy pixel DPX2.

Accordingly, the touch driving circuit 152, which receives a first touch sensing signal transmitted through the first sensing touch electrode Rx1 and a second touch sensing signal transmitted through the second sensing touch electrode Rx2, may cancel gate noise caused by the first-to-third gate circuit block GCB13 and the second-to-fifth gate circuit block GCB25 using the common signal CS that is applied to both the first dummy pixel DPX1 and the second dummy pixel DPX2.

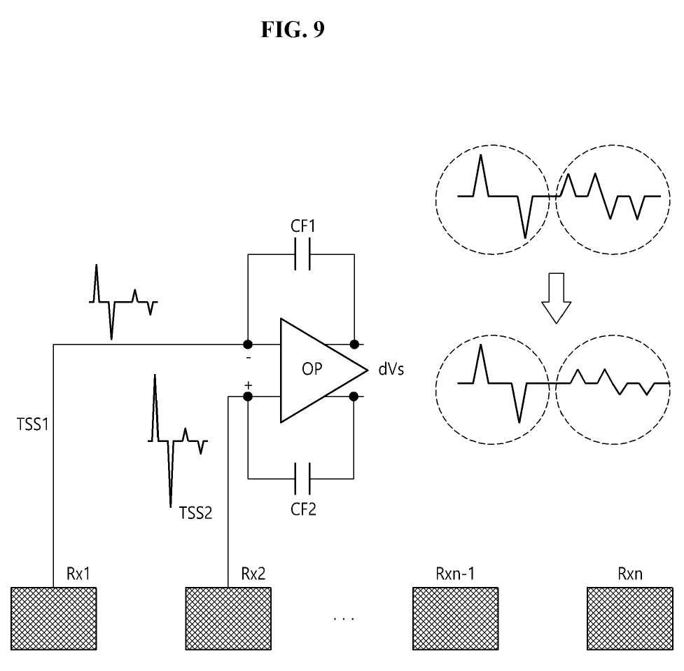

FIG. 9 is a diagram illustrating an example configuration of a differential amplifier in the touch driving circuit that amplifies touch sensing signals in a display device according to embodiments of the invention.

Referring to FIG. 9, the display device 100 according to embodiments of the invention may include n sensing touch electrodes Rx1 to Rxn for touch detection of the display panel 110.

In this case, the touch driving circuit 152 included in the touch circuit 150 may include a differential amplifier OP that compares and amplifies a first touch sensing signal TSS1 transmitted from the first sensing touch electrode Rx1 and a second touch sensing signal TSS2 transmitted from the second sensing touch electrode Rx2.

For example, the first touch sensing signal TSS1 received through the first sensing touch electrode Rx1 may be supplied to an inverting input terminal (−) of the differential amplifier OP, and the second touch sensing signal TSS2 received through the second sensing touch electrode Rx2 may be supplied to a non-inverting input terminal (+) of the differential amplifier OP. The differential amplifier OP may include a first feedback capacitor CF1 to reduce noise of the first touch sensing signal TSS1 and a second feedback capacitor CF2 to reduce noise of the second touch sensing signal TSS2.

In this case, the same common signal CS may be applied to the first dummy pixel DPX1 formed at a position overlapping the first sensing touch electrode Rx1 in the first-to-third gate circuit block GCB13, and to the second dummy pixel DPX2 formed at a position overlapping the second sensing touch electrode Rx2 in the second-to-fifth gate circuit block GCB25.

Accordingly, because the same common signal component is included in both the first touch sensing signal TSS1 and the second touch sensing signal TSS2, the deviation dVs of the signal output through the differential amplifier OP is reduced. As a result, the display device 100 of the invention may reduce the noise deviation caused by the first-to-third gate circuit block GCB13 formed at a position overlapping the first sensing touch electrode Rx1 and the second-to-fifth gate circuit block GCB25 formed at a position overlapping the second sensing touch electrode Rx2, thereby improving touch performance.

This structure may be equally applied to each differential amplifier that receives and amplifies touch sensing signals from adjacent sensing touch electrodes.

According to embodiments of the invention, it is possible to provide a display device and a display panel capable of reducing touch noise and improving touch performance in a display panel having a gate-in-array structure.

According to embodiments of the invention, it is possible to provide a display device and a display panel capable of reducing touch noise by arranging dummy pixels in a gate array area overlapping with touch electrodes and applying a common dummy signal.

According to embodiments of the invention, it is possible to provide a lightweight display device and a display panel capable of realizing a narrow bezel in a non-display area and improving touch performance.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a base circuit layer including a plurality of gate-in-array units constituting a gate driving circuit in a display area;
a pixel layer disposed on the base circuit layer and including a plurality of pixels;
a touch electrode layer disposed over the pixel layer and including a plurality of sensing touch electrodes; and
a touch driving circuit configured to amplify touch sensing signals transmitted through the plurality of sensing touch electrodes to generate touch sensing data,
wherein the plurality of gate-in-array units include:
a first gate circuit block including a first dummy pixel overlapping a first sensing touch electrode; and
a second gate circuit block including a second dummy pixel overlapping a second sensing touch electrode.

2. The display device according to claim 1, wherein the plurality of gate-in-array units include:
a first gate circuit area configured to generate a first scan signal;
a second gate circuit area configured to generate a second scan signal; and
a third gate circuit area configured to generate a light-emission signal, and
wherein each of the first gate circuit area, the second gate circuit area, and the third gate circuit area includes a plurality of gate circuit blocks.

3. The display device according to claim 2, wherein each of the plurality of gate circuit blocks includes:
a sub-circuit area configured to generate a gate signal;
a first pixel driving area in which a first driving voltage line for supplying a driving voltage to a first pixel of the pixel layer is disposed;
a second pixel driving area in which a second driving voltage line for supplying a driving voltage to a second pixel of the pixel layer is disposed; and
a power line area in which a selection signal line for supplying a first selection signal to drive the first pixel and a second selection signal to drive the second pixel is disposed.

4. The display device according to claim 3, wherein the power line area is disposed between the first pixel driving area and the second pixel driving area.

5. The display device according to claim 1, wherein the first dummy pixel has a same size as the second dummy pixel.

6. The display device according to claim 5, wherein the first dummy pixel and the second dummy pixel do not overlap with adjacent gate circuit blocks.

7. The display device according to claim 5, wherein a same common signal is applied to the first dummy pixel and the second dummy pixel.

8. The display device according to claim 7, wherein the touch driving circuit includes a differential amplifier to which a first touch sensing signal from the first sensing touch electrode is supplied to an inverting input terminal, and a second touch sensing signal from the second sensing touch electrode is supplied to a non-inverting input terminal.

9. The display device according to claim 1, wherein:
the first dummy pixel is disposed at an end of the first gate circuit block; and
the second dummy pixel is disposed at an end of the second gate circuit block.

10. A display panel comprising:
a base circuit layer including a plurality of gate-in-array units constituting a gate driving circuit in a display area;
a pixel layer disposed on the base circuit layer and including a plurality of pixels; and
a touch electrode layer disposed over the pixel layer and including a plurality of sensing touch electrodes,
wherein the plurality of gate-in-array units include:
a first gate circuit block including a first dummy pixel overlapping a first sensing touch electrode; and
a second gate circuit block including a second dummy pixel overlapping a second sensing touch electrode.
